(19) United States
(12) Patent Application Publication
(10) Pub. No.: US 2025/0372438 A1
(43) Pub. Date: Dec. 4, 2025

(54) APPARATUS FOR TREATING SUBSTRATE

(71) Applicant: SEMES CO., LTD., Cheonan-si (KR)

(72) Inventors: Hyung Gyu KIM, Ansan-si (KR); Seung Hoon OH, Cheonan-si (KR); Eun Seok KIM, Asan-si (KR)

(73) Assignee: SEMES CO., LTD., Cheonan-si (KR)

(21) Appl. No.: 19/220,172

(22) Filed: May 28, 2025

(30) Foreign Application Priority Data
May 28, 2024 (KR) 10-2024-0069544

(51) Int. Cl. H01L 21/687; B08B 7/00; H01L 21/67

(52) U.S. Cl. CPC H01L 21/68785; B08B 7/0021; H01L 21/67023

(57) ABSTRACT

The present disclosure provides an apparatus for treating substrates. In an embodiment, the apparatus for treating substrates includes: a vessel having a processing space therein; a supply port supplying a process fluid to the processing space; and a pillar unit provided in the vessel and supporting a substrate when the substrate is processed in the vessel, wherein the pillar unit includes: a pillar plate; and legs supporting the pillar plate from an underside of the vessel, and the legs include: a lower pin fixed to the underside of the vessel; and an upper pin detachably coupled to the lower pin and inserted in a through-hole of the pillar plate.

### CROSS-REFERENCE TO RELATED APPLICATIONS

This application claims priority to and the benefit of Korean Patent Application No. 10-2024-0069544 filed in the Korean Intellectual Property Office on May 28, 2024, the entire contents of which are incorporated herein by reference.

### TECHNICAL FIELD

The present disclosure relates to an apparatus for treating substrates and, in more detail, an apparatus for treating substrates using a supercritical liquid.

### BACKGROUND ART

In order to manufacture a semiconductor device, a desired pattern is formed on a substrate through various processes such as photolithography, etching, ashing, ion implantation, and thin film deposition. Various processing solutions are used in the processes, and contaminants and particles are generated during the processes. In order to solve this problem, a cleaning process for cleaning off contaminants and particles is necessarily performed before and after each process.

In general, the cleaning process is performed by processing a substrate with a chemical and a rinse solution and then performing drying. Recently, an organic solvent such as isopropyl alcohol (IPA) has been used as a rinse solution, and drying is performed using a supercritical fluid.

In apparatuses that dry substrates using a supercritical fluid, a pillar that supports substrates is generally disposed in a vessel.

The pillar has a plate and legs extending downward from the plate. To facilitate the removal of the pillar from the vessel, the legs of the pillar are placed on the bottom of the vessel, and the pillar is not fixedly attached to the vessel during processes.

Meanwhile, when drying is performed, if a supercritical fluid is supplied to the lower area of the pillar, vibrations may occur in the pillar or the pillar is rotated or moved due to the supercritical fluid. As a result, particles may be generated inside the pillar, or a wafer may be unevenly dried.

### SUMMARY OF THE INVENTION

An objective of the present disclosure is to provide an apparatus for treating substrates that can effectively process substrates.

An objective of the present disclosure is to provide an apparatus for treating substrates that facilitates adjustment of the height and inclination of a pillar plate supporting substrates.

An objective of the present disclosure is to provide an apparatus for treating substrates that can minimize non-uniformity of temperature of substrates while processing the substrates.

An objective of the present disclosure is to provide an apparatus for treating substrates that facilitates mounting of a pillar unit in a vessel and can prevent vibration, rotation, or movement of the pillar unit while processing substrates.

An objective of the present disclosure is to provide an apparatus for treating substrates that can uniformly dry substrates in a supercritical process.

The objectives of the present disclosure are not limited thereto and other objectives not stated herein may be clearly understood by those skilled in the art from the following description.

An exemplary embodiment of the present disclosure, an apparatus for treating substrates, comprising: a vessel having a processing space therein; a supply port supplying a process fluid to the processing space; and a pillar unit provided in the vessel and supporting a substrate when the substrate is processed in the vessel, wherein the pillar unit includes: a pillar plate; and legs supporting the pillar plate from an underside of the vessel, and the legs include: a lower pin fixed to the underside of the vessel; and an upper pin detachably coupled to the lower pin and inserted in a through-hole of the pillar plate

According to an embodiment of the present disclosure, the pillar unit further may include a fitting ring fitted on an upper portion of the upper pin passing through the through-hole such that the upper pin is fixed to the pillar plate.

According to an embodiment of the present disclosure, the upper pin has: a ring groove at an upper end in which the fitting ring is fitted; and a fitting flange at a lower end for coupling with the lower pin, and the lower pin may have a fitting groove that is open on a side for lateral insertion of the fitting flange and in which the fitting flange is positioned.

According to an embodiment of the present disclosure, the upper pin and the lower pin may be made of different materials.

According to an embodiment of the present disclosure, the upper pin may be made of polyetheretherketone.

According to an embodiment of the present disclosure, the pillar plate further includes supporting pins on a top surface that support a substrate, and the supporting pins may be made of polyetheretherketone.

According to an embodiment of the present disclosure, the apparatus may further include a holder unit provided in the vessel and supporting a substrate when the substrate is loaded into the vessel.

According to an embodiment of the present disclosure, the pillar unit may support a substrate at a position higher than a height at which the substrate is supported by the holder unit.

According to an embodiment of the present disclosure, the lower pin may be provided integrally with the vessel.

According to an embodiment of the present disclosure, a groove defined by an inner surface and a bottom surface is formed on a bottom of the vessel, the pillar plate is positioned higher than the groove, and the supply port may include a first supply port connected to the bottom surface forming the groove.

According to an embodiment of the present disclosure, the process fluid may be a supercritical fluid.

An exemplary embodiment of the present disclosure, an apparatus for treating substrates, comprising: a vessel having a processing space therein and having an upper body and a lower body engaged with each other to switch a closed position at which the processing space is sealed and an open position at which the processing space is opened; a supply port supplying a process fluid to the processing space; and a pillar unit provided at the lower body and supporting a substrate when the substrate is processed in the vessel, wherein the lower body has a groove defined by an inner surface and a bottom surface, and includes fixing pins fixedly installed in the groove to support the pillar unit, and the pillar unit may include: a pillar plate having supporting pins on a top surface that support a substrate; and an upper pin of which an upper end is inserted in a through-hole of the pillar plate and a lower end is detachably coupled and fixed to the fixing pins.

According to an embodiment of the present disclosure, the pillar unit further may include a fitting ring fitted on an upper portion of the upper pin passing through the through-hole such that the upper pin is fixed to the pillar plate.

According to an embodiment of the present disclosure, the upper pin has: a ring groove at an upper end in which the fitting ring is fitted; and a fitting flange at a lower end for coupling with supporting pins, and the supporting pins may have a fitting groove that is open on a side for lateral insertion of the fitting flange and in which the fitting flange is positioned.

According to an embodiment of the present disclosure, the upper pin and the supporting pins may be made of different materials.

According to an embodiment of the present disclosure, the upper pin and the supporting pins may be made of polyetheretherketone.

According to an embodiment of the present disclosure, the apparatus may further include a holder unit provided at the upper body and supporting a substrate when the substrate is loaded into the vessel, wherein the pillar unit may support a substrate at a position higher than a height at which the substrate is supported by the holder unit when the substrate is processed in the vessel.

According to an embodiment of the present disclosure, the fixing pins may be provided integrally with the lower body.

An exemplary embodiment of the present disclosure, an apparatus for treating substrates, comprising: a vessel having a processing space therein and having an upper body and a lower body engaged with each other to switch a closed position at which the processing space is sealed and an open position at which the processing space is opened; a supply port including a first supply port provided on a bottom surface of the lower body to supply a supercritical fluid to the processing space; a holder unit provided at the upper body and supporting a substrate when the substrate is loaded into the vessel; and a pillar unit provided at the lower body and supporting a substrate at a position higher than a height at which the substrate is supported by the holder unit when the substrate is processed in the vessel, wherein the lower body has a groove defined by an inner surface and a bottom surface, and includes fixing pins fixedly installed in the groove to support the pillar unit, the pillar unit includes: a pillar plate having supporting pins on a top surface that support a substrate; legs having an upper pin detachably coupled to a lower pin fixed to an underside of the vessel and inserted in a through-hole of the pillar plate; and a fitting ring fitted on an upper portion of the upper pin passing through the through-hole such that the upper pin is fixed to the pillar plate, the upper pin has: a ring groove at an upper end in which the fitting ring is fitted; and a fitting flange at a lower end for coupling with the lower pin, and the lower pin may have a fitting groove that is open on a side for lateral insertion of the fitting flange and in which the fitting flange is positioned.

According to an embodiment of the present disclosure, the upper pin and the lower pin are made of different materials, the upper pin and the supporting pins are made of polyetheretherketone, a groove defined by an inner surface and a bottom side is formed on a bottom wall of the lower body, the pillar plate is positioned higher than the groove, and the supply port may include a first supply port connected to the bottom surface forming the groove.

According to an embodiment of the present disclosure, it is possible to efficiently process substrates.

According to an embodiment of the present disclosure, it is easy to change the height and inclination of a pillar plate supporting a substrate.

According to an embodiment of the present disclosure, it is possible to minimize non-uniformity of temperature while processing substrates.

According to an embodiment of the present disclosure, it is possible to easily mount a pillar unit in a vessel and prevent vibration, rotation, or movement of the pillar unit while processing substrates.

According to an embodiment of the present disclosure, it is possible to uniformly dry substrate in a supercritical process.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a plan view schematically showing an apparatus for treating substrates according to an embodiment of the present disclosure.

FIG. 2 is a view schematically showing an example of a liquid processing device provided in the apparatus for treating substrates according to an embodiment of the present disclosure.

FIG. 3a is a cross-sectional view showing a supercritical processing device provided in the apparatus for treating substrates according to an embodiment of the present disclosure.

FIG. 3b is a cross-sectional view showing the state in which a vessel of the supercritical processing device of FIG. 3a is open.

FIG. 4 is a plan view illustrating a holder unit and a pillar unit of FIG. 3a.

FIG. 5 is an exploded perspective view of the pillar unit.

FIG. 6 is an enlarged view of a lug and a fitting ring shown in FIG. 5.

FIG. 7 is an enlarged cross-sectional view showing the main parts of the pillar unit shown in FIG. 4.

### DETAILED DESCRIPTION

Hereinafter, an exemplary embodiment of the present invention will be described more fully with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, constituent elements, and components described in the specification or a combination thereof, and do not exclude a possibility of the existence or addition of one or more other characteristics, numbers, operations, constituent elements, and components, or a combination thereof in advance.

Singular expressions used herein include plural expressions unless they have definitely opposite meanings in the context. In addition, shapes, sizes, and the like of the elements in the drawing may be exaggerated for clearer description.

Terms, such as first and second, are used for describing various constituent elements, but the constituent elements are not limited by the terms. The terms may be used to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but other intervening constituent elements may also be present. In contrast, when one constituent element is “directly coupled to or “directly connected to” another constituent element, it should be understood that there are no intervening element is present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

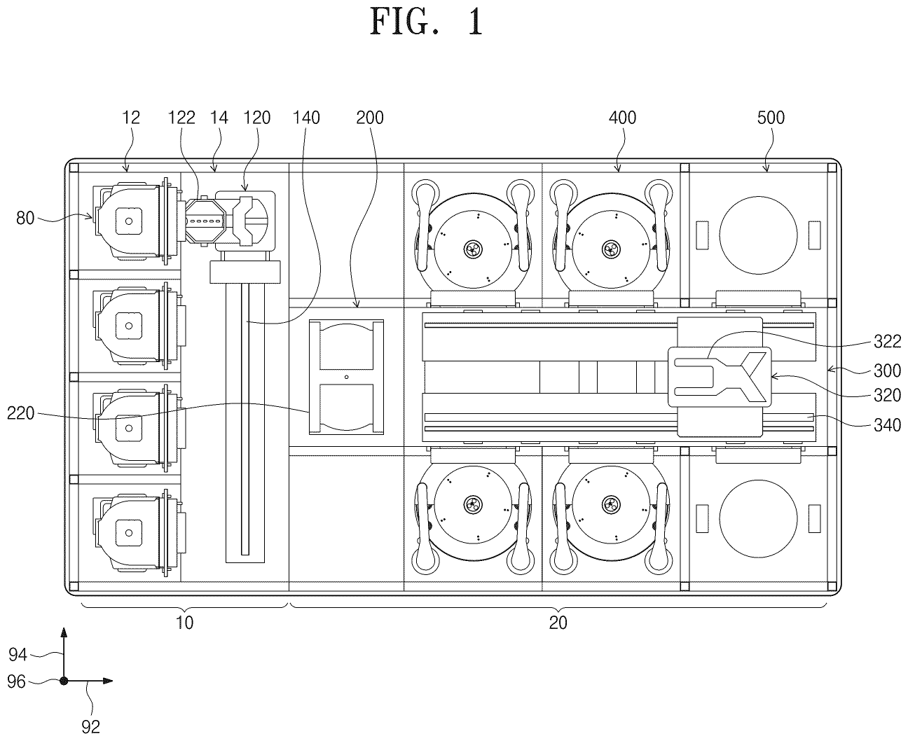

FIG. 1 is a plan view schematically showing a system for treating substrates according to an embodiment of the present disclosure.

Referring to FIG. 1, a system for treating substrates includes an index module 10, a processing module 20, and a control unit 30. According to an embodiment, the index module 10 and the processing module 20 are disposed in one direction. Hereafter, the direction in which the index module 10 and the processing module 20 are arranged is referred to as a first direction 92, a direction perpendicular to the first direction 92 when seen from above is referred to as a second direction 94, and a direction perpendicular to both of the first direction 92 and the second direction 94 is referred to as a third direction 96.

The index module 10 transfers substrates W to the processing module 20 from containers 80 accommodating the substrates W and stores the substrates W processed at the processing module 20 into the containers 80. The longitudinal direction of the index module 10 is provided in the second direction 94. The index module 10 has a loadport 12 and an index frame 14. The loadport 12 is positioned at the opposite side of the processing module 20 with reference to the index frame 14. The containers 80 accommodating substrates W are placed on the loadport 12. A plurality of loadports 12 may be provided and the plurality of load ports 12 may be arranged in the second direction 94.

The container 80 may be a container for sealing such as a Front Open Unified Pod (FOUP). The container 80 may be placed on the loadport 12 by a worker or a conveying device (not shown) such as an overhead transfer, an overhead conveyor, or an automatic guided vehicle.

An index robot 120 is provided on the index frame 14. A guide rail 140 of which the longitudinal direction is provided in the second direction 94 is provided inside the index frame 14 and the index robot 120 may be provided to be movable on the guide rail 140. The index robot 120 includes a hand 122 on which substrates W are placed and the hand 122 may be provided to be able to move forward and backward, rotate about the third direction 96, and move in the third direction 96. A plurality of hands 122 is provided to be spaced apart from each other in the vertical direction and the hands 122 can move forward and backward independently from each other.

The processing module 20 includes a buffer unit 200, a transfer device 300, a liquid processing device 400, and a supercritical processing device 500. The buffer unit 200 provides a space in which substrates W that are loaded into the processing module 20 and substrates W that are unloaded from the processing module 20 temporarily stay. The liquid processing device 400 performs liquid processing process of performing liquid processing on substrates W by supplying a liquid onto the substrates W. The supercritical processing device 500 performs a drying process that removes a liquid remaining on substrates W. The transfer device 300 transfers substrates W among the buffer unit 200, the liquid processing device 400, and the supercritical processing device 500.

The longitudinal direction of the transfer device 300 may be provided in the first direction 92. The buffer unit 200 may be disposed between the index module 10 and the transfer device 300. The liquid processing device 400 and the supercritical processing device 500 may be disposed on sides of the transfer device 300. The liquid processing device 400 and the transfer device 300 may be arranged in the second direction 94. The supercritical processing device 500 and the transfer device 300 may be arranged in the second direction 94. The buffer unit 200 may be positioned at an end of the transfer device 300.

According to an embodiment, the liquid processing devices 400 may be disposed at both sides of the transfer device 300, the supercritical processing devices 500 may be disposed at both sides of the transfer device 300, and the liquid processing devices 400 may be disposed at positions closer to the buffer unit 200 than the supercritical processing devices 500. The liquid processing devices 400 may be provided in an array of A×B (A and B are each a natural number of 1 or more) in the first direction 92 and the third direction 96, respectively, at a side of the transfer device 300. The supercritical processing devices 500 may be provided by the number of C×D (C and D are each a natural number of 1 or more) in the first direction 92 and the third direction 96, respectively, at a side of the transfer device 300. Unlike the above description, only the liquid processing devices 400 may be provided at a side of the transfer device 300 and only the supercritical processing devices 500 may be provided at another side.

The transfer device 300 has a transfer robot 320. A guide rail 340 of which the longitudinal direction is provided in the first direction 92 is provided in the transfer device 300 and the transfer robot 320 may be provided to be movable on the guide rail 340. The transfer robot 320 includes a hand 322 on which substrates W are placed and the hand 322 may be provided to be able to move forward and backward, rotate about the third direction 96, and move in the third direction 96. A plurality of hands 322 is provided to be spaced apart from each other in the vertical direction and the hands 322 can move forward and backward independently from each other.

The buffer unit 200 has a plurality of buffers 220 on which substrates W are placed. The buffers 220 may be disposed to be spaced apart from each other in the third direction 96. The buffer unit 200 is open on the front face and the rear face. The front face is a surface that faces the index module 10 and the rear face is a surface that faces the transfer device 300. The index robot 120 can approach the buffer unit 200 through the front face and the transfer robot 320 can approach the buffer unit 200 through the rear face.

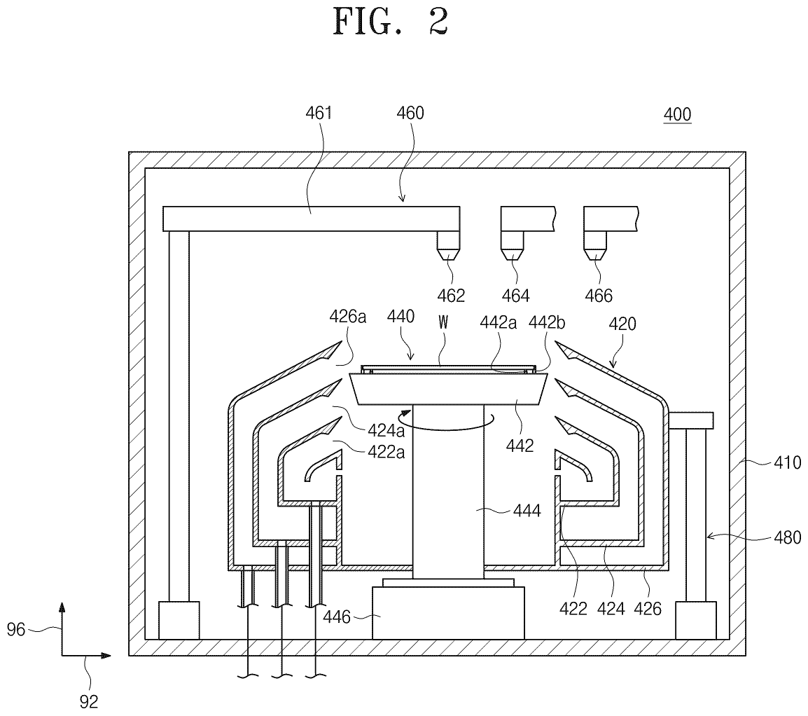

FIG. 2 is a view schematically showing an example of a liquid processing device provided in the apparatus for treating substrates according to an embodiment of the present disclosure.

FIG. 2 is a view schematically showing an embodiment of the liquid processing device of FIG. 1.

Referring to FIG. 2, the liquid processing device 400 includes a housing 410, a cup 420, a supporting unit 440, a liquid supply unit 460, and a lifting unit 480. The housing 410 is provided substantially in a rectangular parallelepiped shape. The cup 420, the supporting unit 440, and the liquid supply unit 460 are disposed in the housing 410.

The cup 420 has a processing space with an open top and substrates W are liquid-processed in the processing space. The supporting unit 440 supports substrates W in the processing space. The liquid supply unit 460 supplies liquid to a substrate W supported on the supporting unit 440. A plurality of types of liquids are provided and may be sequentially supplied to a substrate W. The lifting unit 480 adjusts the relative height between the cup 420 and the supporting unit 440.

According to an example, the cup 420 has a plurality of collection tanks 422, 424, and 426. The collection tanks 422, 424, and 426 each have a collection space for collecting liquid used to process substrates. The collection tanks 422, 424, and 426 are each provided in a ring shape surrounding the supporting unit 440. The processing solutions scattered by rotation of a substrate W when the liquid processing process is performed flow into the collection spaces through inlets 422a, 424a, and 426a of the collection tanks 422, 424, and 426, respectively. According to an example, the cup 420 has a first collection tank 422, a second collection tank 424, and a third collection tank 426. The first collection tank 422 is disposed to surround the supporting unit 440, the second collection tank 424 is disposed to surround the first collection tank 422, and the third collection tank 426 is disposed to surround the second collection tank 424. The second inlet 424a for supplying liquid into the second collection tank 424 is positioned higher than the first inlet 422a for supplying liquid into the first collection tank 422, and the third inlet 426a for supplying liquid into the third collection tank 426 may be positioned higher than the second inlet 424a.

The supporting unit 440 has a supporting plate 442 and an actuating shaft 444. The top surface of the supporting plate 442 is provided substantially in a circular shape and may have a diameter larger than substrates W. Supporting pins 442a supporting the back side of a substrate W are provided at the center portion of the supporting plate 442 and are provided such that the upper ends thereof protrude from the supporting plate 442 to space a substrate W a predetermined distance from the supporting plate 442. Chuck pins 442b are provided on the edge portion of the supporting plate 442. The chuck pins 442b protrude upward from the supporting plate 442 and support the side of a substrate W to prevent the substrate W from deviating from the supporting unit 440 when the substrate W is rotated. The driving shaft 444 is driven by an actuator 446, is connected to the center of the underside of a substrate W, and rotates the supporting plate 442 about the center axis thereof.

According to an embodiment, the liquid supply unit 460 has a first nozzle 462, a second nozzle 464, and a third nozzle 466. The first nozzle 462 supplies a first liquid to substrates W. The first liquid may be liquid that removes a film or foreign substances remaining on a substrate W. The second nozzle 464 supplies a second liquid to substrates W. The second liquid may be liquid that is dissolved well in a third liquid. For example, the second liquid may be liquid that is dissolved well in the third liquid in comparison to the first liquid. The second liquid may be liquid that neutralizes the first liquid supplied to a substrate W. Further, the second liquid may be liquid that neutralizes the first liquid and is dissolved well in the third liquid in comparison to the first liquid. According to an example, the second liquid may be water. The third nozzle 466 supplies a third liquid to substrates W. The third liquid may be liquid that is dissolved well in a supercritical fluid that is used in the supercritical processing device 500. For example, the third liquid may be liquid that is dissolved well in a supercritical fluid that is used in the supercritical processing device 500 in comparison to the second liquid. According to an example, the third liquid may be an organic solvent. The organic solvent may be isopropyl alcohol (IPA). Further, the organic solvent include, in addition to isopropyl alcohol, ethyl glycol, 1-propanol, tetrahydrofuran, 4-hydroxy, 4-methyl, 2-pentanone, 1-butanol, 2-butanol, methanol, ethanol, n-propyl alcohol, dimethyl ether, etc. According to an example, the supercritical fluid may be carbon dioxide. The first nozzle 462, the second nozzle 464, and the third nozzle 466 are supported by different arms 461 and the arms 461 can be independently moved. Optionally, the first nozzle 462, the second nozzle 464, and the third nozzle 466 may be mounted on the same arm and moved simultaneously.

The lifting unit 480 moves the cup 420 in the vertical direction. The relative height between the cup 420 and a substrate W is changed by vertical movement of the cup 420. Accordingly, the collection tanks 422, 424, and 426 that collect processing solutions are switched, depending on the types of liquids that are supplied to substrates W, so it is possible to separately collect liquids. Unlike the above description, the cup 420 is fixedly installed and the lifting unit 480 may move the supporting unit 440 in the vertical direction.

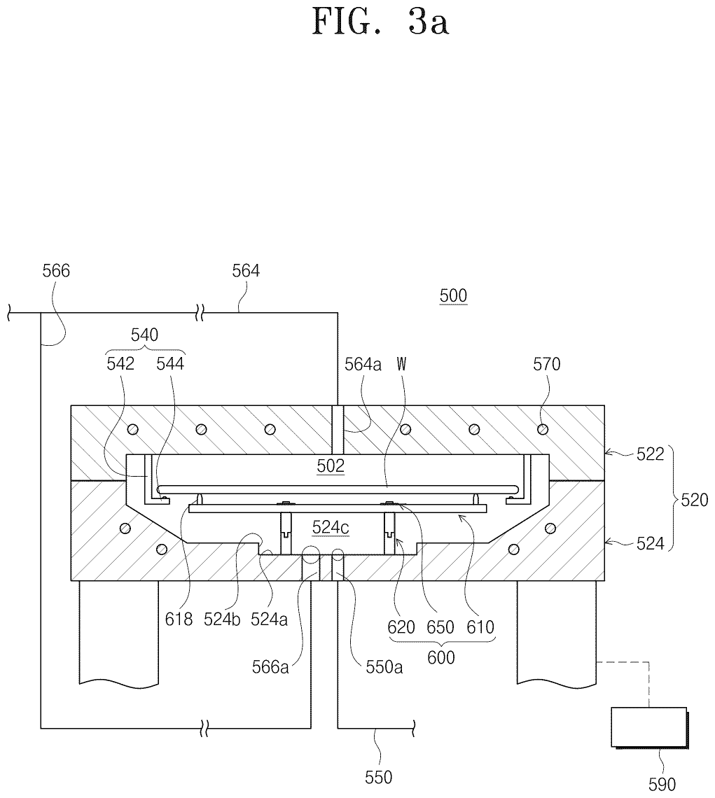

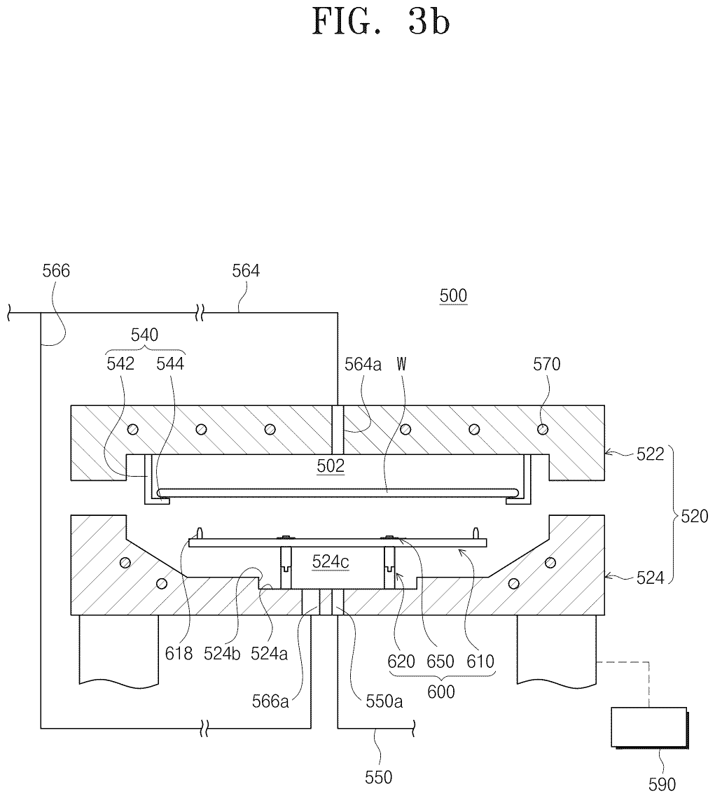

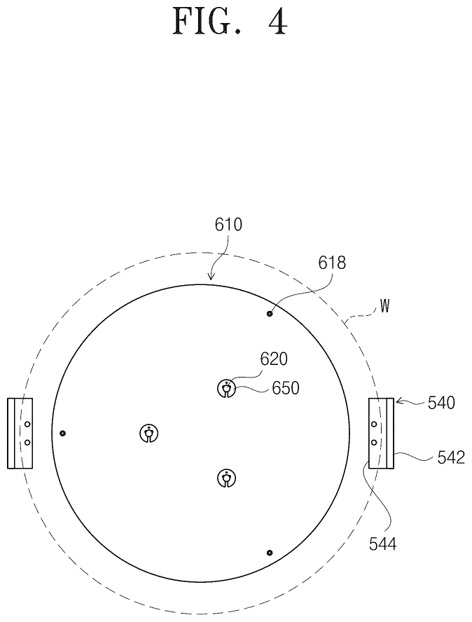

FIG. 3a is a cross-sectional view schematically showing an embodiment of the supercritical processing device of FIG. 1, FIG. 3b is a cross-sectional view showing the state in which a vessel of the supercritical processing device of FIG. 3a is open, and FIG. 4 is a plan view illustrating a holder unit and a pillar unit of FIG. 3a.

Referring to FIG. 3a to FIG. 4, the supercritical processing device 500 processes liquid-processed substrates with a supercritical fluid. According to an embodiment, the supercritical processing device 500 dries substrates W using a supercritical fluid. Carbon dioxide (CO2) in a supercritical state may be used as the supercritical fluid. Carbon dioxide enters a supercritical state when the temperature is increased to 30° C. or higher and the pressure is maintained at 7.4 MPa or higher. Hereafter, it is exemplified in the following description that carbon dioxide in a supercritical state is used as a process fluid.

According to an embodiment, the supercritical processing device 500 removes liquid on substrates W using a supercritical fluid. The supercritical processing device 500 may include a vessel 520, a holder unit 540, a fluid supply unit 560 and a pillar unit 600.

The vessel 520 provides a processing space 502 in which the supercritical process is performed. The vessel 520 is made of a material capable of withstanding the critical temperature and the critical pressure of a supercritical fluid. The vessel 520 may include an upper body 522 and a lower body 524.

A space with an open underside is formed in the upper body 522. The top of the upper body 522 is provided as the top of the vessel 520. Further, the side walls of the upper body 522 are provided as a portion of the side walls of the vessel 520. The lower body 524 is positioned under the upper body 522. A space with an open top surface is formed in the lower body 524. The open top surface of the lower body 524 faces the open bottom surface of the upper body 522. The bottom of the lower body 524 is provided as the bottom of the vessel 520. Further, the side walls of the lower body 524 are provided as a portion of the side walls of the vessel 520. The upper body 522 and the lower body 524 provide the processing space 502 by combining with each other.

The upper body 522 and the lower body 524 can open or seal the processing space 502 by relatively moving. An actuating member 590 moves at least any one of the upper body 522 and the lower body 524 in the vertical direction. The actuating member 590 may be a hydraulic device. According to an embodiment, the position of the upper body 522 is fixed and the lower body 524 may be moved up and down by the actuating member 590 such as a cylinder. When the lower body 524 is spaced from the upper body 522, the processing space 502 is opened and a substrate W is loaded or unloaded. When a process is performed, the lower body 524 comes in close contact with the upper body 522, whereby the processing space 502 is sealed from the outside.

The supercritical processing device 500 has heater 570. According to an embodiment, the heater 570 is positioned in the wall of the vessel 520. In an embodiment, the heater 570 may be provided in any one of the upper body 522 and the lower body 524 constituting the vessel 520, or in each of the upper body 522 and the lower body 524. The heater 570 heats the processing space 502 of the vessel 520 such that the fluid supplied into the processing space 502 of the vessel 520 maintains a supercritical state. An atmosphere by a supercritical fluid is formed in the processing space 502.

A groove 524c defined by the bottom surface 524a and the inner surface 524b is formed on the bottom of the vessel 520. The groove 524c may be formed with a predetermined depth. The groove may be provided in a circular shape.

A first supply port 566a and a second supply port 564a are formed in the vessel 520. The first supply port 566a and the second supply port 564a supply a supercritical fluid into the vessel 520.

The first supply port 566a may be provided in the center region of the bottom of the vessel 520. The first supply port 566a may be provided in the region in which the groove 524c of the vessel 520 is formed. The first supply port 566a is formed at a position where it passes through the bottom in the vertical direction. The first supply port 566a supplies a supercritical fluid to the space positioned under a substrate W, in the internal space 502 of the vessel 520.

The second supply port 564a may be provided in the top of the vessel 520. The second supply port 564a supplies a supercritical fluid to the space positioned over a substrate W, in the internal space 502 of the vessel 520. The supercritical fluid supplied from the second supply port 564a is provided onto the top side of a substrate W.

An exhaust port 550a exhausts fluid remaining in the vessel 520 to the outside. The exhaust port 550a may be formed in the bottom of the vessel 520. The exhaust port 550a may be positioned adjacent to the first supply port 566a. The exhaust port 550a may be in the center region of the bottom surface of the vessel 520. The exhaust port 550a may be provided in the region in which the groove 524c of the vessel 520 is formed. In an embodiment, the exhaust port 550a is formed at a position where it passes through the bottom in the vertical direction. In an embodiment, the diameter of the exhaust port 550a is smaller than the diameter of the first supply port 566a. The fluid that is exhausted through the exhaust port 550a includes a supercritical fluid in which an organic solvent is dissolved. The fluid exhausted from the exhaust port 550a may be sent to a recycling apparatus (not shown). The fluid can be separated into a supercritical fluid and the organic solvent in the recycling apparatus. Unlike this, the fluid exhausted from the exhaust port 550a may be discharged to the atmosphere through an exhaust line 550. As another example, the exhaust port and the first supply port may be provided as a single common port. That is, a lower branch line 566 is connected to the common port, and in this state the exhaust line 550 is connected to the lower branch line. In a supercritical supply step, the lower branch line 566 is opened and the exhaust line 550 is turned off, and in an exhaust step, the lower branch line 566 is turned off and the exhaust line 550 is opened.

The fluid supply unit 560 supplies a process fluid into the processing space 502 of the vessel 520. According to an embodiment, the process fluid can be supplied into the processing space 502 in a supercritical state. Unlike this, the process fluid is supplied into the processing space 502 in a gas state and the phase thereof may be changed into a supercritical state in the processing space 502. According to an example, the fluid supply unit 560 has a main supply line 562, an upper branch line 564, and a lower branch line 566. The upper branch line 564 and the lower branch line 566 diverge from the main supply line 562. The upper branch line 564 is coupled to the second supply port 564a and supplies a process fluid over a substrate W placed on the holder unit 540. The lower branch line 566 is coupled to the first supply port 566a and supplies a process fluid under a substrate W placed on the holder unit 540. The exhaust line 550 is coupled to the exhaust port 550a. The supercritical fluid in the processing space 502 of the vessel 520 is exhausted to the outside of the vessel 520 through the exhaust line 550.

The holder unit 540 supports a substrate W that is loaded in the processing space 502 of the vessel 520. A substrate W that is loaded/unloaded into/from the vessel 520 at an open position of the vessel 520 can be temporarily supported by the holder unit 540. The holder unit 540 may have a fixing rod 542 and a holder 544. The fixing rods 542 may be fixed to the upper body 522 to protrude downward from the underside of the upper body 522. The longitudinal direction of the fixing rod 542 may be provided in the vertical direction. A plurality of fixing rods 542 are provided and may be positioned to be spaced apart from each other. The fixing rods 542 are disposed such that a substrate W does not interfere with the fixing rods 542 when the substrate W is loaded into or unloaded from a space surrounded by the fixing rods 542. The holder 544 is coupled to lower end of each of the fixing rods 542. The holder 544 extends from the lower ends of the fixing rods 542 in parallel with the ground. In an embodiment, the holder 544 extends in a shape that can support the lower edge of a substrate W. The holder 544 can support the edge region of a substrate W.

A pillar unit 600 is disposed in the processing space 502 of the vessel 520.

The pillar unit 600 may include supporting pins 618 supporting a substrate. At a closed position of the vessel 520, the supporting pins 618 of the pillar unit 600 can support a substrate W at a position higher than the height at which it is supported by the holder unit 540. The supporting pins 618 can support the edge region of a substrate at a position where they do not interfere with the holder 544. The supporting pins 618 are disposed on the edge of the pillar plate 610, but are not limited thereto and may be disposed on the pillar plate 610 to support the center region of a substrate.

When the lower body 524 is moved downward and the vessel 520 is opened, the pillar unit 600 can be moved downward with the lower body 524. Next, a substrate W can be loaded into the vessel and can be seated on the holder unit. As shown in FIG. 3a, when the lower body 524 is moved upward and the vessel is closed, the supporting pins of the pillar unit can be moved upward with the lower body 524. Since at the closed position of the vessel, the supporting pins of the pillar unit have a height larger than the substrate-supporting position of the holder unit, a substrate can be seated on the supporting pins of the pillar unit that is moving upward. Next, a supercritical drying process can be performed on the substrate W supported by the pillar unit.

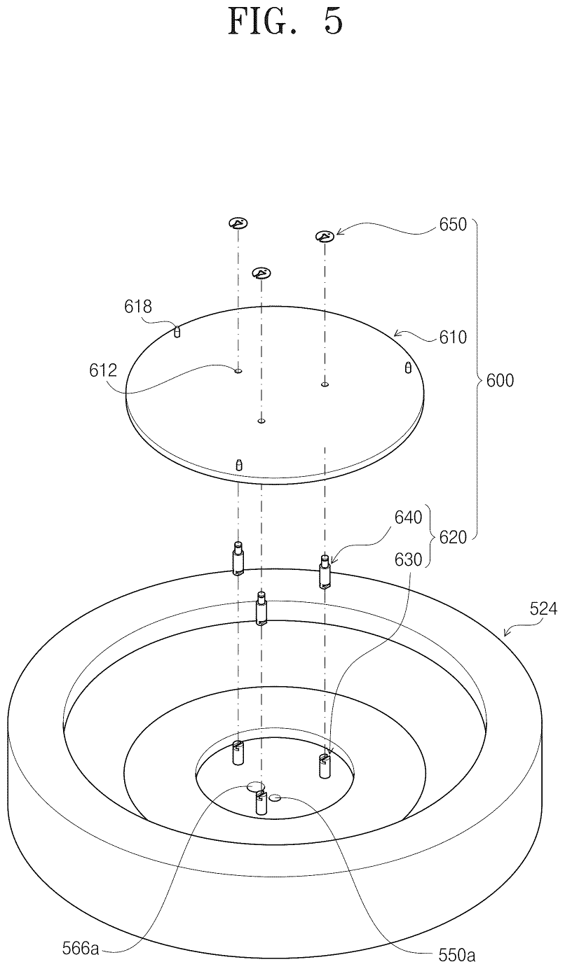

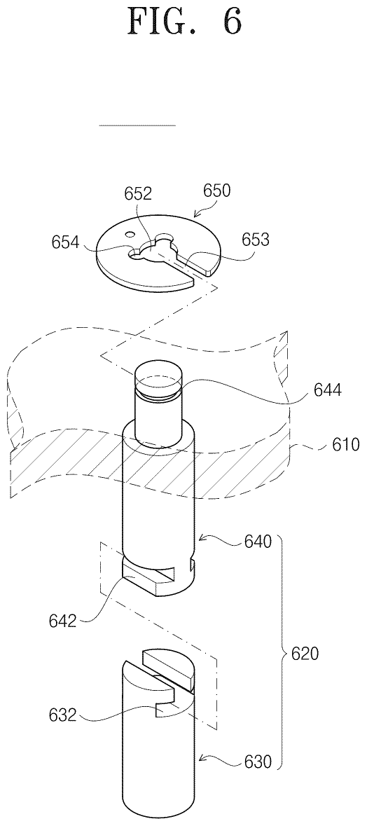

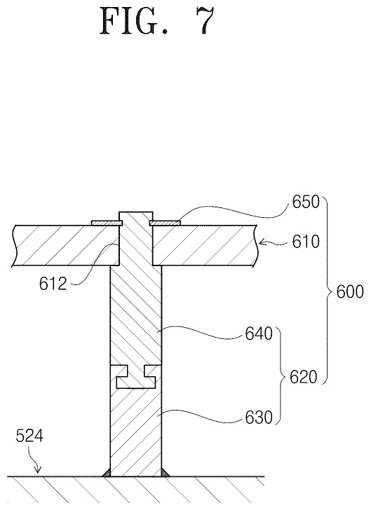

FIG. 5 is an exploded perspective view of the pillar unit, FIG. 6 is an enlarged view of a lug and a fitting ring shown in FIG. 5, and FIG. 7 is an enlarged cross-sectional view showing the main parts of the pillar unit shown in FIG. 4.

Referring to FIG. 5 to FIG. 7, the pillar unit 600 is positioned under the holder unit 540. The pillar unit 600 may include a pillar plate 610, a plurality of legs 620, and a fitting ring 650.

The pillar plate 610 is disposed to face a substrate W supported by the holder unit 540. The plurality of legs 620 extend downward from the bottom surface of the pillar plate 610.

The pillar plate 610 is positioned to be spaced apart from the bottom of the vessel 520. The pillar plate 610 is positioned higher than the groove 524c of the vessel 520. When viewed from above, the area of the pillar plate 610 is larger than the area of the groove 524c of the vessel 520. The pillar plate 610 can stop direct spray of the supercritical fluid supplied from the first supply port 566a to the back side of a substrate W.

Pins 618 that support a substrate may be provided on the top surface of the pillar plate 610. Three supporting pins 618 may be provided. The three supporting pins 618 may be arranged with the same intervals. The three supporting pins 618 may be spaced at 120° intervals on a concentric circle. The supporting pins 618 may be made of polyetheretherketone.

The plurality of legs 620 supports the pillar plate 610 in the vessel 520. The legs 620 can be separated into a lower pin 630 and an upper pin 640. The lower pin 630 can be fixed to the underside of the vessel 520. For example, the lower pin 630 can be fixedly coupled to the underside of the lower body 524 by welding, etc. The upper pin 640 may be detachably coupled to the lower pin 630. The upper pin 640 can be inserted into a through-hole 612 of the pillar plate 610. The upper pin 640 has a ring groove 644 at the upper end in which the fitting ring 650 is fitted, and a fitting flange 642 at the lower end for coupling with the lower pin 630. The lower pin 630 has a fitting groove 632 that is open on a side for lateral insertion of the fitting flange 642 and in which the fitting flange 642 is positioned.

According to an embodiment, the plurality of legs 620 may be three legs. The three legs 620 may be arranged with the same intervals. The three legs 620 may be spaced at 120° intervals on a concentric circle. In this case, a circle is defined by the three legs 620. The center of the circle is the same as the center of the pillar plate 610.

The upper pin 640 and the lower pin 630 having this structure are easily detachably coupled to each other, and when the upper pin 640 is replaced by an upper pin having another length, it is easy to change the height and adjust the inclination of the pillar plate 610.

The upper pin 640 and the lower pin 630 may be made of different materials. For example, the lower pin 630 may be made of stainless steel, the same as the lower body524, and the upper pin 640 may be made of polyetheretherketone. The upper pin 640 that is in contact with the pillar plate 610 is made of a material with thermal conductivity lower than the material of the lower pin 630, whereby it is possible to minimize the heat that transfers to the pillar plate 610 through the legs 620 from the vessel 520. By minimizing heat transfer in this way, it is possible to prevent temperature imbalance of substrates.

The fitting ring 650 is fitted on the upper portion (in the ring groove 644) of the upper pin 640 passing through the through-hole 612 of the pillar plate 610 to prevent the upper pin 640 from being pulled out of the pillar plate 610 in the longitudinal direction of the pin. In more detail, a circular pin hole 652 is formed at the center of the fitting ring 650 and a side of the pin hole 652 is cut off, whereby a disc shape that is partially open is achieved. Grooves 654 for easy mounting or separating with respect to the upper pin 640 are formed at the pin hole 652. The grooves 654 facilitate elastic deformation of the fitting ring 650 during mounting or separating with respect to the upper pin 640. When the fitting ring 650 is inserted into the ring groove 644 of the upper pin 640 with the opening 653 at the front and then strongly pushed inward, the opening 653 is elastically deformed outward and then restored, whereby it is fitted in the ring groove 644.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. An apparatus for treating substrates, comprising:
a vessel having a processing space therein;
a supply port supplying a process fluid to the processing space; and
a pillar unit provided in the vessel and supporting a substrate when the substrate is processed in the vessel,
wherein the pillar unit includes:
a pillar plate; and
legs supporting the pillar plate from an underside of the vessel, and
the legs include:
a lower pin fixed to the underside of the vessel; and
an upper pin detachably coupled to the lower pin and inserted in a through-hole of the pillar plate.

2. The apparatus of claim 1, wherein the pillar unit further includes a fitting ring fitted on an upper portion of the upper pin passing through the through-hole such that the upper pin is fixed to the pillar plate.

3. The apparatus of claim 2, wherein the upper pin has:
a ring groove at an upper end in which the fitting ring is fitted; and
a fitting flange at a lower end for coupling with the lower pin, and
the lower pin has a fitting groove that is open on a side for lateral insertion of the fitting flange and in which the fitting flange is positioned.

4. The apparatus of claim 2, wherein the upper pin and the lower pin are made of different materials.

5. The apparatus of claim 4, wherein the upper pin is made of polyetheretherketone.

6. The apparatus of claim 2, wherein the pillar plate further includes supporting pins on a top surface that support a substrate, and
the supporting pins are made of polyetheretherketone.

7. The apparatus of claim 2, further comprising a holder unit provided in the vessel and supporting a substrate when the substrate is loaded into the vessel.

8. The apparatus of claim 7, wherein the pillar unit supports a substrate at a position higher than a height at which the substrate is supported by the holder unit.

9. The apparatus of claim 2, wherein the lower pin is provided integrally with the vessel.

10. The apparatus of claim 2, wherein a groove defined by an inner surface and a bottom surface is formed on a bottom of the vessel,
the pillar plate is positioned higher than the groove, and
the supply port includes a first supply port connected to the bottom surface of the groove.

11. The apparatus of claim 10, wherein the process fluid is a supercritical fluid.

12. An apparatus for treating substrates, comprising:
a vessel having a processing space therein and having an upper body and a lower body engaged with each other to switch a closed position at which the processing space is sealed and an open position at which the processing space is opened;
a supply port supplying a process fluid to the processing space; and
a pillar unit provided at the lower body and supporting a substrate when the substrate is processed in the vessel,
wherein the lower body has a groove defined by an inner surface and a bottom surface, and includes fixing pins fixedly installed in the groove to support the pillar unit, and
the pillar unit includes:
a pillar plate having supporting pins on a top surface that support a substrate; and
an upper pin of which an upper end is inserted into a through-hole of the pillar plate and a lower end is detachably coupled and fixed to the fixing pins.

13. The apparatus of claim 12, wherein the pillar unit further includes a fitting ring fitted on an upper portion of the upper pin passing through the through-hole such that the upper pin is fixed to the pillar plate.

14. The apparatus of claim 13, wherein the upper pin has:
a ring groove at an upper end in which the fitting ring is fitted; and
a fitting flange at a lower end for coupling with supporting pins, and
the supporting pins have a fitting groove that is open on a side for lateral insertion of the fitting flange and in which the fitting flange is positioned.

15. The apparatus of claim 13, wherein the upper pin and the supporting pins are made of different materials.

16. The apparatus of claim 15, wherein the upper pin and the supporting pins are made of polyetheretherketone.

17. The apparatus of claim 12, further comprising a holder unit provided at the upper body and supporting a substrate when the substrate is loaded into the vessel,
wherein the pillar unit supports a substrate at a position higher than a height at which the substrate is supported by the holder unit when the substrate is processed in the vessel.

18. The apparatus of claim 13, wherein the fixing pins are provided integrally with the lower body.

19. An apparatus for treating substrates, comprising:
a vessel having a processing space therein and having an upper body and a lower body engaged with each other to switch a closed position at which the processing space is sealed and an open position at which the processing space is opened;
a supply port including a first supply port provided on a bottom surface of the lower body to supply a supercritical fluid to the processing space;
a holder unit provided at the upper body and supporting a substrate when the substrate is loaded into the vessel; and
a pillar unit provided at the lower body and supporting a substrate at a position higher than a height at which the substrate is supported by the holder unit when the substrate is processed in the vessel,
wherein the lower body has a groove defined by an inner surface and a bottom surface, and includes fixing pins fixedly installed in the groove to support the pillar unit,
the pillar unit includes:
a pillar plate having supporting pins on a top surface that support a substrate;
legs having an upper pin detachably coupled to a lower pin fixed to an underside of the vessel and inserted in a through-hole of the pillar plate; and
a fitting ring fitted on an upper portion of the upper pin passing through the through-hole such that the upper pin is fixed to the pillar plate,
the upper pin has:
a ring groove at an upper end in which the fitting ring is fitted; and
a fitting flange at a lower end for coupling with the lower pin, and
the lower pin has a fitting groove that is open on a side for lateral insertion of the fitting flange and in which the fitting flange is positioned.

20. The apparatus of claim 19, wherein the upper pin and the lower pin are made of different materials,
the upper pin and the supporting pins are made of polyetheretherketone,
a groove defined by an inner surface and a bottom surface is formed on a bottom wall of the lower body,
the pillar plate is positioned higher than the groove, and
the supply port includes a first supply port connected to the bottom surface forming the groove.
